(19) United States
(12) Patent Application Publication
(10) Pub. No.: US 2026/0157223 A1
(43) Pub. Date: Jun. 4, 2026

(54) SEMICONDUCTOR PACKAGE, AND METHOD FOR FORMING THE SAME

(71) Applicant: JCET STATS ChipPAC Korea Limited, Incheon (KR)

(72) Inventors: WonSang RHEE, Incheon (KR); JoonSung PARK, Incheon (KR); DaeHyun KWON, Seoul (KR)

(21) Appl. No.: 19/405,444

(22) Filed: Dec. 2, 2025

(30) Foreign Application Priority Data
Dec. 4, 2024 (CN) 202411773138.5

(51) Int. Cl. H10W 74/10; H10W 72/00; H10W 74/01; H10W 90/00; H10W 90/10; H10W 90/20

(52) U.S. Cl. CPC H10W 74/111; H10W 72/823; H10W 74/01; H10W 90/10; H10W 90/291; H10W 90/724

(57) ABSTRACT

A semiconductor package and a method for forming the same are provided. The method may include: providing a substrate having a top surface and a bottom surface, wherein the top surface of the substrate has a first region and a second region; mounting a first electronic component and a first interconnection structure on the first region; forming a first encapsulant to encapsulate the first electronic component and the first interconnection structure, wherein the first encapsulant is formed in the first region but outside the second region; forming a conductive pattern on the first encapsulant to electrically connect with the first interconnection structure; mounting a second electronic component on the second region; and mounting a third electronic component on the first encapsulant to electrically connect with the conductive pattern.

### TECHNICAL FIELD

The present application generally relates to semiconductor technology, and more particularly, to a semiconductor package, and a method for forming the same.

### BACKGROUND OF THE INVENTION

The semiconductor industry is constantly faced with complex integration challenges as consumers want their electronics to be smaller, faster and higher performance with more and more functionalities packed into a single device. Recently, System-in-Package (SiP) and Double Side Molding (DSM) are developed to improve the degree of integration of electronic components. SiP is a functional electronic system or sub-system that includes in a single package two or more heterogeneous semiconductor dice, such as a logic chip, a memory, integrated passive devices (IPD), RF filters, sensors, heat sinks, or antennas. DSM packages have a two side assembly structure and typically adopt a fine pitch Surface Mount Technology (SMT) process for small form factor.

However, a need exists for further improvement to the degree of integration of electronic components in a semiconductor package.

### SUMMARY OF THE INVENTION

An objective of the present application is to provide a method for improving the degree of integration of electronic components in a semiconductor package.

According to an aspect of the present application, a method for forming a semiconductor package is provided. The method may include: providing a substrate having a top surface and a bottom surface, wherein the top surface of the substrate has a first region and a second region; mounting a first electronic component and an interconnection structure on the first region; forming a first encapsulant to encapsulate the first electronic component and the interconnection structure, wherein the first encapsulant is formed in the first region but outside the second region; forming a conductive pattern on the first encapsulant to electrically connect with the interconnection structure; mounting a second electronic component on the second region; and mounting a third electronic component on the first encapsulant to electrically connect with the conductive pattern.

According to another aspect of the present application, a semiconductor package is provided. The semiconductor package may include: a substrate having a top surface and a bottom surface, wherein the top surface of the substrate has a first region and a second region; a first electronic component mounted on the first region; an interconnection structure mounted on the first region; a first encapsulant encapsulating the first electronic component and the interconnection structure, wherein the first encapsulant is formed in the first region but outside the second region; a conductive pattern formed on the first encapsulant and electrically connected with the interconnection structure; a second electronic component mounted on the second region; and a third electronic component mounted on the first encapsulant and electrically connected with the conductive pattern.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view of a semiconductor package according to an embodiment of the present application.

FIGS. 2A to 2F are cross-sectional views illustrating various steps of a method for forming a semiconductor package according to an embodiment of the present application.

FIG. 3 is a cross-sectional view of a semiconductor package according to another embodiment of the present application.

FIGS. 4A to 4D are cross-sectional views illustrating various steps of a method for forming a semiconductor package according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

According to an aspect of the present application, a semiconductor package is provided. The semiconductor package may include a substrate, at least one first electronic component and an interconnection structure mounted on a first region of a top surface of the substrate, and at least one second electronic component mounted on a second region of the top surface of the substrate. A first encapsulant is formed in the first region but outside the second region to selectively mold the first electronic component and the interconnection structure. A conductive pattern is formed on the first encapsulant and electrically connected with the interconnection structure, and then at least one third electronic component is mounted on the first encapsulant and electrically connected with the conductive pattern. In the semiconductor package, the first encapsulant and the interconnection structure are used to provide additional space above the first electronic component, such that the third electronic component can be disposed above the first electronic component. Therefore, more electronic components can be integrated into the semiconductor package without increasing its footprint, and a degree of integration of electronic components is improved in the semiconductor package.

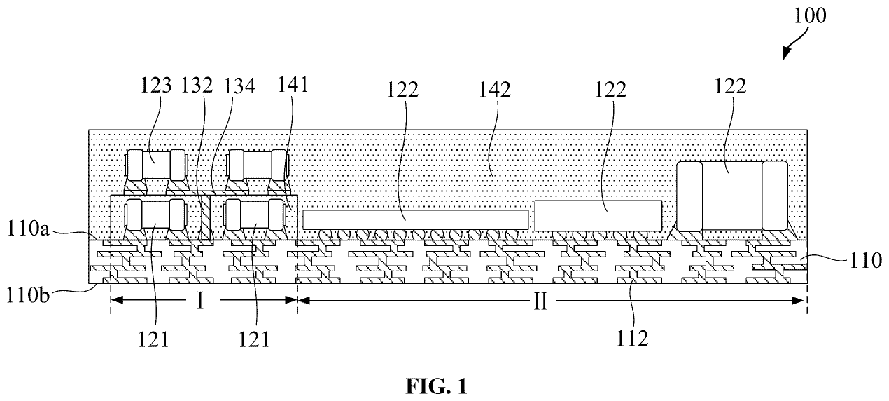

FIG. 1 illustrates a cross-sectional view of a semiconductor package 100 according to an embodiment of the present application.

The semiconductor package 100 may include a substrate 110, at least one first electronic component 121 and an interconnection structure 132 mounted on a first region I of a top surface 110a of the substrate 110, and at least one second electronic component 122 mounted on a second region II of the top surface 110a of the substrate 110. In some embodiments, the substrate 110 may be a printed circuit board (PCB), laminate interposer, wafer-form, strip interposer, leadframe, or another suitable substrate that can support and interconnect various electronic components. For example, the substrate 110 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The substrate 110 can also be a multi-layer flexible laminate, ceramic, copper clad laminate, or glass.

In some embodiments, the substrate 110 may include a plurality of wiring layers, which define pads, traces and plugs through which electrical signals or voltages can be distributed horizontally and vertically across the substrate 110. The wiring layers may include one or more of Cu, Al, Sn, Ni, Au, Ag, or any other suitable electrically conductive materials. For example, as shown in FIG. 1, the substrate 110 may include redistribution structures (RDS) 112. The redistribution structures 112 may include one or more dielectric layers and one or more conductive layers between and through the dielectric layers. The conductive layers may provide contact pads along the top surface 110a and the bottom surface 110b of the substrate 110 for mounting devices, chips, and interconnects thereon. It could be appreciated that, the wiring layers may be implemented in various structures and types, but aspects of the present application are not limited to the above example.

In the example shown in FIG. 1, the first region I is a left portion of the top surface 110a of the substrate 110, and the second region I is a right portion of the top surface 110a of the substrate 110. However, the present application is not limited thereto. In some other examples, the first region I may be a central portion or a peripheral portion of the top surface 110a of the substrate 110. The first electronic component 121 and the interconnection structure 132 are mounted on the first region I, and the second electronic component 122 are mounted on the second region II of the top surface 110a of the substrate 110.

The first electronic component 121 and the second electronic component 122 may include any of a variety of types of semiconductor dice, semiconductor packages, or discrete devices. For example, the first electronic component 121 and the second electronic component 122 may include one or more digital chips, analog chips or mixed signal chips, such as application specific integrated circuit (ASIC) chips, sensor chips, wireless and radio frequency (RF) chips, memory chips, logic chips or voltage regulator chips. The first electronic component 121 and the second electronic component 122 may also include one or more passive electronic components such as resistors, capacitors, inductors, etc. Depending on their structures and configurations, the first electronic component 121 and the second electronic component 122 may be mounted on the contact pads formed on the top surface 110a of the substrate 110 in a flip-chip configuration, or by wire bonding or any other suitable surface mounting techniques.

In the example shown in FIG. 1, the first electronic component 121 includes two discrete devices (for example, two passive electronic components such as resistors, capacitors or inductors). The discrete devices may have a smaller size and dissipate less heat during operation, which is beneficial for stacking other devices thereon. The second electronic component 122 include two semiconductor dice and one discrete device having a greater height. That is, the height of the discrete device of the second electronic component 122 is greater than heights of the two discrete devices of the first electronic component 121. In the example shown in FIG. 1, the interconnection structure 132 is between the two discrete devices of the first electronic component 121. However, the present application is not limited thereto. It could be understood that, the types, sizes, shapes and/or locations of the first electronic component 121, the second electronic component 122 and the interconnection structure 132 in the above embodiment may be exemplary only, and are not restrictive of the invention.

In some embodiments, the interconnection structure 132 may include one or more conductive pillars. For example, the conductive pillars may be copper pins. However, the present application is not limited thereto. In other examples, the conductive pillars may include aluminum, nickel-plated copper, nickel-plated aluminum, or other materials with a high conductivity. In some other embodiments, the interconnection structure 132 may include one or more preformed e-bar blocks that include built-in conductive pillars such as copper pillars and an insulative base material separating the copper pillars from each other. In some embodiments, the interconnection structure 132 may be mounted on contact pads formed in the first region I via solder bumps or using other suitable surface mounting techniques.

Continuing referring to FIG. 1, a first encapsulant 141 is formed in the first region I but outside the second region II to selectively encapsulate the first electronic component 121 and the interconnection structure 132. The first encapsulant 141 can provide mechanical protection for the first electronic component 121 and the interconnection structure 132, and more importantly, provide physical support for other electronic components mounted thereon. The first encapsulant 141 may include, for example, an epoxy molding compound (EMC), a polymide compound, or any other suitable dielectric materials. As shown in FIG. 1, a top surface of the first encapsulant 141 may be coplanar with a top surface of the interconnection structure 132. That is, the interconnection structure 132 extends from the top surface to the bottom surface of the first encapsulant 141 to provide various signal/power paths which extend generally vertically between the substrate 110 and electronic components mounted on the first encapsulant 141.

As shown in FIG. 1, a conductive pattern 134 is formed on the first encapsulant 141 and electrically connected with the interconnection structure 132, and at least one third electronic component 123 is mounted on the first encapsulant 141 and electrically connected with the conductive pattern 134. The conductive pattern 134 may include copper, aluminum, nickel, silver, gold, or other suitable conductive materials. The conductive pattern 134 may define pads and/or traces on the top surface of the first encapsulant 141. The conductive pattern 134 together with the interconnection structure 132 can provide electrical connections between the third electronic component 123 and the wiring layers in the substrate 110.

The third electronic component 123 may include any of a variety of types of semiconductor dice, semiconductor packages, or discrete devices, and will not be elaborated herein. The third electronic component 123 may have a footprint smaller than that of the first encapsulant 141, and have a smaller thickness to reduce the thickness of the semiconductor package 100. In the example shown in FIG. 1, the third electronic component 123 is mounted on the first encapsulant 141 by flip-chip bonding with its contact pads facing the conductive pattern 134 formed on the top surface of the first encapsulant 141. However, the present application is not limited thereto. In other embodiments, the third electronic component 123 may be mounted on the encapsulant 141 by wire bonding or any other suitable surface mounting techniques.

In addition, a second encapsulant 142 is formed on the top surface 110a of the substrate 110. The second encapsulant 142 encapsulates the first encapsulant 141, the second electronic component 122 and the third electronic component 123. The second encapsulant 142 covers the entire top surface 110 a of the substrate 110 exposed from the first encapsulant 141, and the top and lateral surfaces of the first encapsulant 141. The second encapsulant 142 can provide mechanical protection, environmental protection, and a hermetic seal for the semiconductor package 100, and may be made from, for example, an epoxy molding compound (EMC), a polymide compound, or any other suitable dielectric materials.

In some embodiments, the semiconductor package 100 may further include a plurality of conductive bumps or solder balls (not shown) formed on contact pads along the bottom surface 110b of the substrate 110. The conductive bumps or solder balls can be used to interface with an external device or attach the semiconductor package 100 to an external device or substrate, such as a printed circuit board (PCB).

According to another aspect of the present application, a method for forming a semiconductor package is provided.

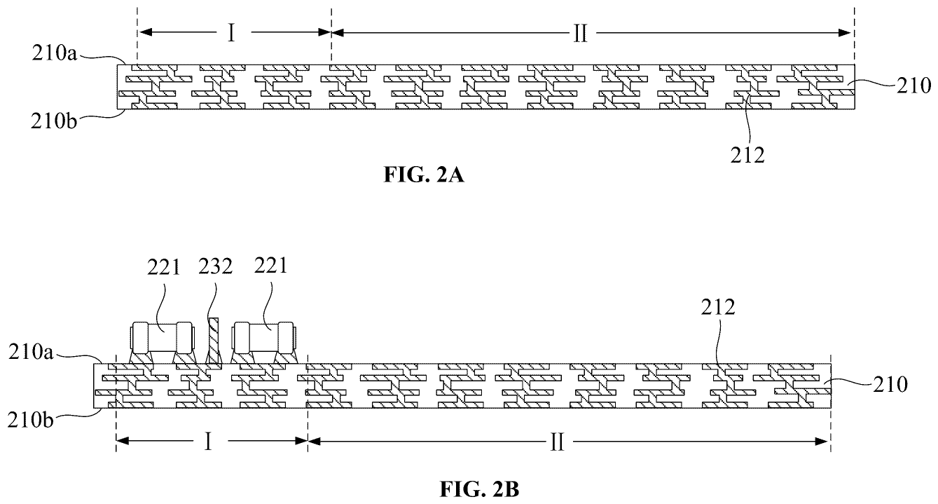

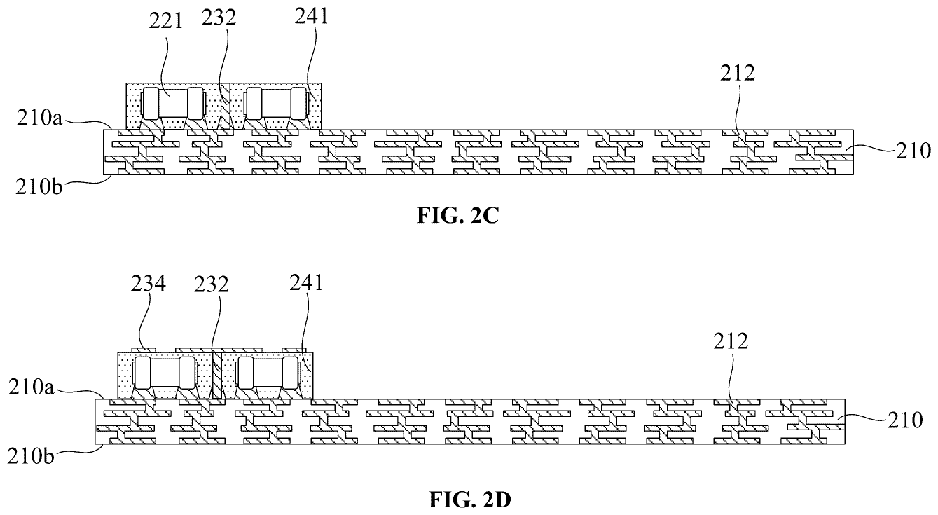

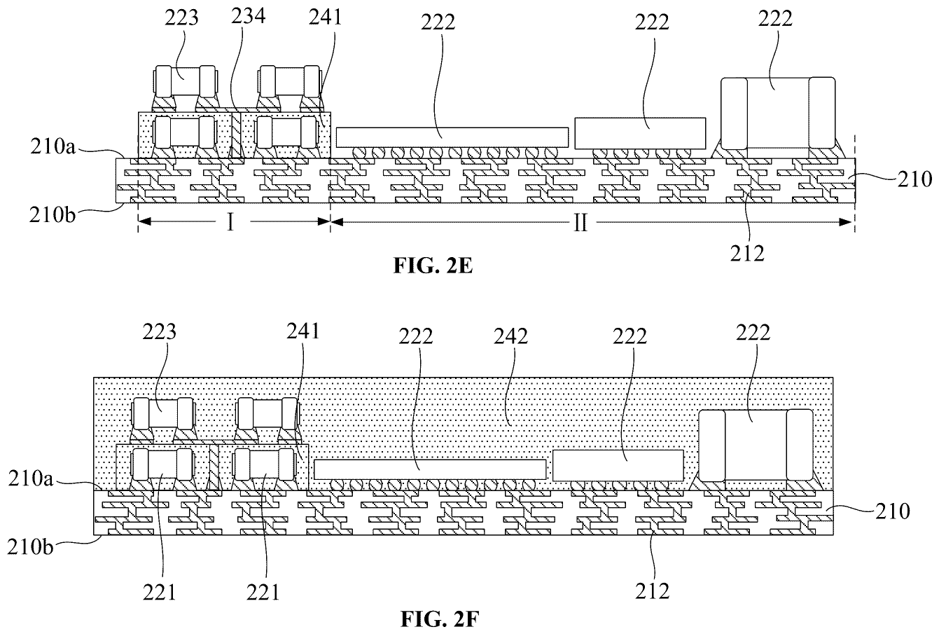

Referring to FIGS. 2A to 2F, various steps of a method for forming a semiconductor package are illustrated according to an embodiment of the present application. For example, the method may be used to form the semiconductor package 100 illustrated in FIG. 1. In the following, the method will be described with references to FIGS. 2A to 2F in more details.

Referring to FIG. 2A, a substrate 210 is provided. In some embodiments, the substrate 210 may be a printed circuit board (PCB), laminate interposer, wafer-form, strip interposer, leadframe, or another suitable substrate that can support and interconnect various electronic components. In some embodiments, the substrate 210 may include a plurality of wiring layers, which define pads, traces and plugs through which electrical signals or voltages can be distributed horizontally and vertically across the substrate 210. For example, as shown in FIG. 2A, the substrate 210 may include redistribution structures (RDS) 212. The redistribution structures 212 may include one or more dielectric layers and one or more conductive layers between and through the dielectric layers. The conductive layers may provide contact pads along the top surface 210a and the bottom surface 210b of the substrate 210 for mounting devices, chips, and interconnects thereon. It could be appreciated that, the wiring layers may be implemented in various structures and types, but aspects of the present application are not limited to the above example.

As shown in FIG. 2A, the substrate 210 has a top surface 210a and a bottom surface 210b, and the top surface 210a of the substrate 210 has a first region I and a second region II. In subsequent processes, two or more layers of electronic components may be stacked within the first region I but outside the second region II. In the example shown in FIG. 2A, the first region I is a left portion of the top surface 210a of the substrate 210, and the second region II is a right portion of the top surface 210a of the substrate 210. However, the present application is not limited thereto. In some other examples, the first region I may be a central portion or a peripheral portion of the top surface 210a of the substrate 210.

Referring to FIG. 2B, at least one first electronic component 221 and an interconnection structure 232 is mounted on the first region I.

Depending on its structure and configuration, the first electronic component 221 may be mounted on the contact pads formed on the top surface 210a of the substrate 210 in a flip-chip configuration, or by wire bonding or any other suitable surface mounting techniques. The first electronic component 221 may include any of a variety of types of semiconductor dice, semiconductor packages, or discrete devices.

In the example shown in FIG. 2B, the first electronic component 221 includes two discrete devices (for example, two passive electronic components such as resistors, capacitors or inductors). The discrete devices may have a smaller size and dissipate less heat during operation, which is beneficial for stacking other devices thereon.

The interconnection structure 232 may be mounted on contact pads formed in the first region I via solder bumps or using other suitable surface mounting techniques. In some embodiments, the interconnection structure 232 may include one or more conductive pillars. For example, the conductive pillars may be copper pins. However, the present application is not limited thereto. In other examples, the conductive pillars may include aluminum, nickel-plated copper, nickel-plated aluminum, or other materials with a high conductivity. In some other embodiments, the interconnection structure 232 may include one or more preformed e-bar blocks that include built-in conductive pillars such as copper pillars and an insulative base material separating the copper pillars from each other.

In the example shown in FIG. 2B, the interconnection structure 232 is disposed between the two discrete devices of the first electronic component 221. However, the present application is not limited thereto. It could be understood that, the types, sizes, shapes and/or locations of the first electronic component 221 and the interconnection structure 232 in the above embodiment may be exemplary only, and are not restrictive of the invention.

Referring to FIG. 2C, a first encapsulant 241 is formed in the first region I but outside the second region II to selectively encapsulate the first electronic component 221 and the interconnection structure 232.

In some embodiments, a selective molding process is employed to form the first encapsulant 241. For example, a molding chase defining the geometry of the first encapsulant 241 may be provided, and then the molding material may be injected or compressed into the molding chase to form the first encapsulant 241. The molding material may include, for example, an epoxy molding compound (EMC), a polymide compound, or any other suitable dielectric materials. In some embodiments, a grinder may be used to grind the top surface of the first encapsulant 241 to expose a top surface of the interconnection structure 232. The grinding process can also planarize the top surface of the first encapsulant 241, such that an exposed surface of the interconnection structure 232 is coplanar with the top surface of the first encapsulant 241. Thus, the interconnection structure 232 can extend from the top surface to the bottom surface of the first encapsulant 241 to provide various signal/power paths which extend generally vertically between the substrate 210 and electronic components mounted on the first encapsulant 241.

In some embodiments, a film assisted molding (FAM) technique may be used to form the first encapsulant 241. For example, a film may be attached on an inner surface of a molding chase, and then the molding chase is placed over the substrate 210 to define a geometry of the first encapsulant 241. The film is sandwiched between the molding chase and the interconnection structure 232. Afterwards, the molding material is injected into the molding chase. After the molding material is solidified, the molding chase and the film is removed from the top surface of the interconnection structure 232. In some cases, the film may include a Teflon-based material, and thus can be easily released from the interconnection structure 232. Accordingly, the top surface of the interconnection structure 232 can be kept clear of sticky molding material.

However, the present application is not limited to the above embodiments. In some other embodiments, the first encapsulant 241 may be formed using a paste printing, transfer molding, liquid encapsulant molding, vacuum lamination, spin coating, or other suitable applicator.

Referring to FIG. 2D, a conductive pattern 234 is formed on the first encapsulant 241 to electrically connect with the interconnection structure 232.

In some embodiments, a conductive layer may be formed on the top surface of the first encapsulant 241 by using sputtering, electrolytic plating, electroless plating, or other suitable deposition process. The conductive layer is electrically connected with the interconnection structure 232. Then, the conductive layer is patterned to form the conductive pattern 234. For example, a laser patterning process may be used to pattern the conductive layer. In some other embodiments, the conductive pattern 234 may be formed using other additive, semi-additive, or subtractive metal deposition techniques. The conductive pattern 234 may include copper, aluminum, nickel, silver, gold, or other suitable conductive materials. The conductive pattern 234 may define pads and/or traces on the top surface of the first encapsulant 241. The conductive pattern 234 together with the interconnection structure 232 can provide electrical connections between the wiring layers in the substrate 210 and electronic components mounted on the first encapsulant 241.

Referring to FIG. 2E, at least one second electronic component 222 is mounted on the second region II of the top surface 210a of the substrate 210. Depending on its structure and configuration, the second electronic component 222 may be mounted on the contact pads formed on the top surface 210a of the substrate 210 in a flip-chip configuration, or by wire bonding or any other suitable surface mounting techniques. The second electronic component 222 may include any of a variety of types of semiconductor dice, semiconductor packages, or discrete devices. For example, the second electronic component 222 may include semiconductor dice dissipating more heat than the first electronic component 221 during operation, and/or discrete devices having a greater height than the first electronic component 221. It could be understood that, the types, sizes, shapes and/or locations of the second electronic component 222 shown in FIG. 2E may be exemplary only, and are not restrictive of the invention.

Continuing referring to FIG. 2E, at least one third electronic component 223 is mounted on the first encapsulant 241 to electrically connect with the conductive pattern 234. In some embodiments, the third electronic component 223 may be mounted on the first encapsulant 241 by flip-chip bonding with its contact pads facing the conductive pattern 234 formed on the top surface of the first encapsulant 241. However, the present application is not limited thereto. In other embodiments, the third electronic component 223 may be mounted on the encapsulant 241 by wire bonding or any other suitable surface mounting techniques. The third electronic component 223 may include any of a variety of types of semiconductor dice, semiconductor packages, or discrete devices, and will not be elaborated herein. The third electronic component 223 may have a footprint smaller than that of the first encapsulant 241, and have a smaller thickness to reduce the thickness of the semiconductor package.

Referring to FIG. 2F, a second encapsulant 242 is formed on the top surface 210 a of the substrate 210 to encapsulate the first encapsulant 241, the second electronic component 222 and the third electronic component 223.

In some embodiments, an overall molding process is performed to form the second encapsulant 242 to covers the entire top surface 210a of the substrate 210 exposed from the first encapsulant 241, and the top and lateral surfaces of the first encapsulant 241. In some embodiments, the second encapsulant 242 may be formed using a paste printing, transfer molding, liquid encapsulant molding, vacuum lamination, spin coating, or other suitable applicator, and may include, for example, an epoxy molding compound (EMC), a polymide compound, or any other suitable dielectric materials. The second encapsulant 242 can provide mechanical protection, environmental protection, and a hermetic seal for the semiconductor package.

In some embodiments, a plurality of conductive bumps or solder balls (not shown) may be further formed on contact pads along the bottom surface 210b of the substrate 210. The conductive bumps or solder balls can be used to interface with an external device or attach the semiconductor package to an external device or substrate, such as a printed circuit board (PCB).

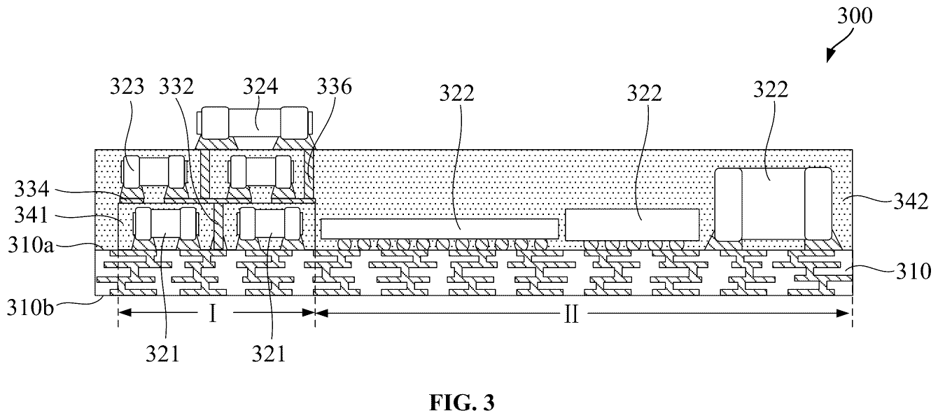

Referring to FIG. 3, a cross-sectional view of a semiconductor package 300 is illustrated according to an embodiment of the present application.

As illustrated in FIG. 3, the semiconductor device 300 includes a substrate 310. The substrate 310 has a top surface 310a and a bottom surface 310b, and the top surface 310a of the substrate 310 has a first region I and a second region II. At least one first electronic component 321 and at least one first interconnection structure 332 are mounted on the first region I. A first encapsulant 341 is formed to encapsulate the first electronic component 321 and the first interconnection structure 332. The first encapsulant 341 is formed in the first region I but outside the second region II. A conductive pattern 334 is formed on the first encapsulant 341 and electrically connected with the first interconnection structure 332. Further, at least one second electronic component 322 is mounted on the second region II and at least one third electronic component 323 is mounted on the first encapsulant 341 and electrically connected with the conductive pattern 334. A second encapsulant 342 is formed on the top surface 310a of the substrate 310 and encapsulates the first encapsulant 341, the second electronic component 322 and the third electronic component 323. The semiconductor package 300 may have some similar or same structures and configurations as the semiconductor package 100 shown in FIG. 1. The similar or same parts between the semiconductor package 300 and the semiconductor package 100 will not be repeated herein.

A difference existing between the semiconductor package 300 and the semiconductor package 100 is that a second interconnection structure 336 is also mounted on the first encapsulant 341 and electrically connected with the conductive pattern 334. The second encapsulant 342 encapsulates the second interconnection structure 336 but exposes a top surface of the second interconnection structure 336. The second interconnection structure 336 may include one or more conductive pillars such as copper pins, and/or one or more preformed e-bar blocks. The second interconnection structure 336 may extend from the top surface of the second encapsulant 342 to the top surface of the first encapsulant 341 to provide various signal/power paths which extend generally vertically between the conductive pattern 334 and electronic components mounted on the top surface of the second encapsulant 342.

Further, at least one fourth electronic component 324 is mounted on the top surface of the second encapsulant 342 and electrically connected with the second interconnection structure 336. The fourth electronic component 324 may include any of a variety of types of semiconductor dice, semiconductor packages, or discrete devices, and will not be elaborated herein. In some embodiments, an additional conductive pattern may be formed on the top surface of the second encapsulant 342, and the fourth electronic component 324 may be mounted on the second encapsulant 342 by flip-chip bonding with its contact pads facing the additional conductive pattern formed on the top surface of the second encapsulant 342. However, the present application is not limited thereto. In other embodiments, the fourth electronic component 324 may be mounted on the second encapsulant 342 by wire bonding or any other suitable surface mounting techniques.

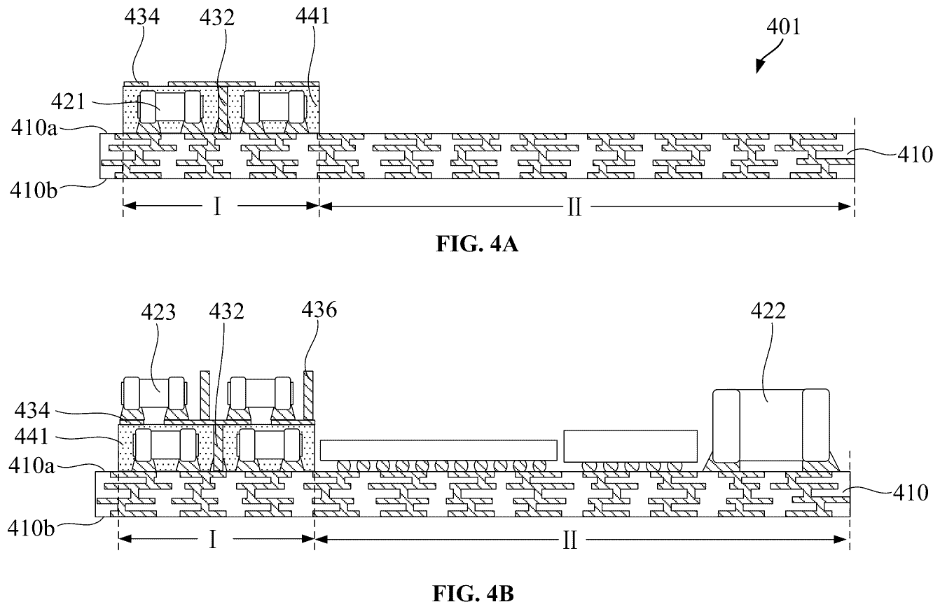

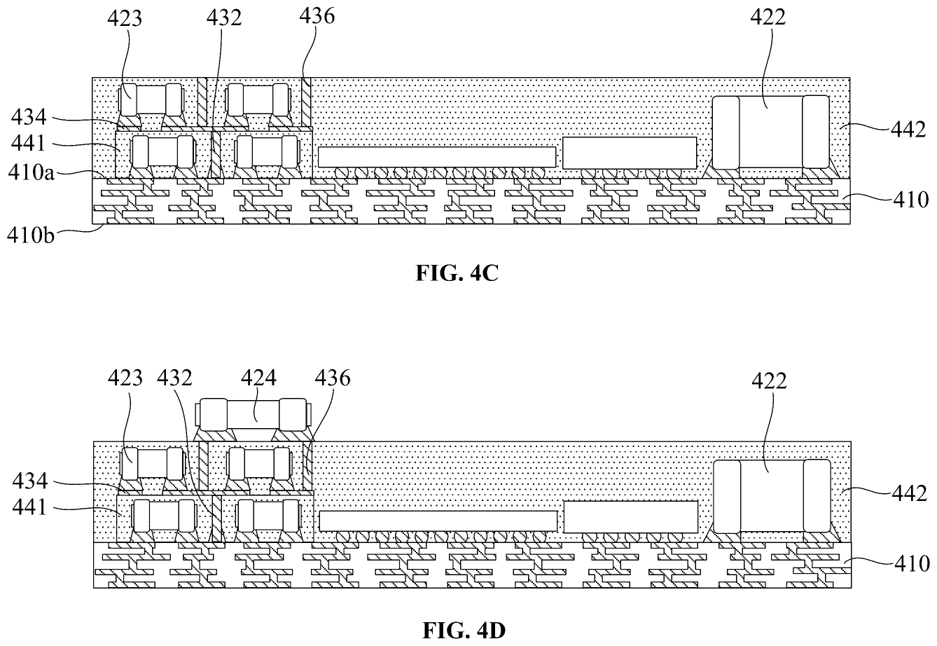

Referring to FIGS. 4A to 4D, cross-sectional views illustrating various steps of a method for forming a semiconductor package are illustrated according to an embodiment of the present application. For example, the method may be used to form the semiconductor package 300 illustrated in FIG. 3.

As shown in FIG. 4A, a sub-package 401 is provided. The sub-package 401 includes a substrate 410. The substrate 410 has a top surface 410a and a bottom surface 410b, and the top surface 410a of the substrate 410 has a first region I and a second region II. At least one first electronic component 421 and at least one first interconnection structure 432 are mounted on the first region I. A first encapsulant 441 is formed to encapsulate the first electronic component 421 and the first interconnection structure 432. The first encapsulant 441 is formed in the first region I but outside the second region II. A conductive pattern 434 is formed on the first encapsulant 441 and electrically connected with the first interconnection structure 432. The package structure shown in FIG. 4A is similar to the structure shown in FIG. 2D, and will not be elaborated herein.

Afterwards, referring to FIG. 4B, at least one second electronic component 422 is mounted on the second region II of the top surface 410a of the substrate 410. Depending on its structure and configuration, the second electronic component 422 may be mounted on the contact pads formed on the top surface 410a of the substrate 410 in a flip-chip configuration, or by wire bonding or any other suitable surface mounting techniques. The second electronic component 422 may include any of a variety of types of semiconductor dice, semiconductor packages, or discrete devices.

Continuing referring to FIG. 4B, at least one third electronic component 423 and a second interconnection structure 436 are mounted on the first encapsulant 441 to electrically connect with the conductive pattern 434. In some embodiments, the third electronic component 423 may be mounted on the first encapsulant 441 by flip-chip bonding with its contact pads facing the conductive pattern 434 formed on the top surface of the first encapsulant 441. The third electronic component 423 may include any of a variety of types of semiconductor dice, semiconductor packages, or discrete devices, and will not be elaborated herein. The third electronic component 423 may have a footprint smaller than that of the first encapsulant 441. The second interconnection structure 436 may be mounted on the conductive pattern 434 formed on the top surface of the first encapsulant 441 via solder bumps or using other suitable surface mounting techniques. In some embodiments, the second interconnection structure 436 may include one or more conductive pillars such as copper pins. In some other embodiments, the second interconnection structure 436 may include one or more preformed e-bar blocks that include built-in conductive pillars such as copper pillars and an insulative base material separating the copper pillars from each other. In some examples, as shown in FIG. 4B, a top surface of the second interconnection structure 436 may be higher than a top surface of the third electronic component 423.

Referring to FIG. 4C, a second encapsulant 442 is formed on the top surface 410a of the substrate 410 to encapsulate the first encapsulant 441, the second electronic component 422, the third electronic component 423 and the second interconnection structure 436.

In some embodiments, an overall molding process is performed to form the second encapsulant 442 to covers the entire top surface 410a of the substrate 410 exposed from the first encapsulant 441, and the top and lateral surfaces of the first encapsulant 441. Meanwhile, the third electronic component 423 and the second interconnection structure 436 are also encapsulated by the second encapsulant 442. Then, a grinder may be used to grind the top surface of the second encapsulant 442 to expose a top surface of the second interconnection structure 436. Thus, the second interconnection structure 436 can extend from the top surface of the second encapsulant 442 to the top surface of the first encapsulant 441 to provide various signal/power paths which extend generally vertically between the conductive pattern 434 and electronic components mounted on the top surface of the second encapsulant 442. In some embodiments, a film assisted molding (FAM) technique may be used to form the second encapsulant 442, and the grinding process can be omitted. However, the present application is not limited to the above embodiments. The second encapsulant 442 may be formed using a paste printing, transfer molding, liquid encapsulant molding, vacuum lamination, spin coating, or other suitable applicator, and may include, for example, an epoxy molding compound (EMC), a polymide compound, or any other suitable dielectric materials.

Then, referring to FIG. 4D, at least one fourth electronic component 424 is mounted on the second encapsulant 442 and electrically connected with the second interconnection structure 436.

In some embodiments, as shown in FIG. 4D, the fourth electronic component 424 may be mounted on the second encapsulant 442 by flip-chip bonding with its contact pads facing the second interconnection structure 436 exposed from the top surface of the second encapsulant 442. However, the present application is not limited thereto. In other embodiments, depending on its structure and configuration, the second interconnection structure 436 may be mounted on the second encapsulant 442 by wire bonding or any other suitable surface mounting techniques. The fourth electronic component 424 may include any of a variety of types of semiconductor dice, semiconductor packages, or discrete devices, and will not be elaborated herein.

In some embodiments, an additional conductive pattern may be formed on the top surface of the second encapsulant 442, and the fourth electronic component 424 may be electrically connected with the second interconnection structure 436 via the additional conductive pattern.

The discussion herein included numerous illustrative figures that showed various portions of a semiconductor package and a method for forming a semiconductor package. For illustrative clarity, such figures did not show all aspects of each exemplary method or package. Any of the example packages and/or methods provided herein may share any or all characteristics with any or all other packages and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor package, comprising:
providing a substrate having a top surface and a bottom surface, wherein the top surface of the substrate has a first region and a second region;
mounting a first electronic component and a first interconnection structure on the first region;
forming a first encapsulant to encapsulate the first electronic component and the first interconnection structure, wherein the first encapsulant is formed in the first region but outside the second region;
forming a conductive pattern on the first encapsulant to electrically connect with the first interconnection structure;
mounting a second electronic component on the second region; and
mounting a third electronic component on the first encapsulant to electrically connect with the conductive pattern.

2. The method of claim 1, further comprising:
forming a second encapsulant on the top surface of the substrate to encapsulate the first encapsulant, the second electronic component and the third electronic component.

3. The method of claim 1, wherein a top surface of the first encapsulant is coplanar with a top surface of the first interconnection structure.

4. The method of claim 3, wherein forming a conductive pattern on the first encapsulant comprises:
forming a conductive layer on the top surface of the first encapsulant to electrically connect with the first interconnection structure; and
patterning the conductive layer to form the conductive pattern.

5. The method of claim 4, wherein the conductive layer is patterned using a laser patterning process.

6. The method of claim 1, wherein the third electronic component is mounted on the first encapsulant by flip-chip bonding.

7. The method of claim 1, further comprising:
mounting a second interconnection structure on the first encapsulant to electrically connect with the conductive pattern; and
forming a second encapsulant on the top surface of the substrate to encapsulate the first encapsulant, the second electronic component, the third electronic component and the second interconnection structure.

8. The method of claim 7, further comprising:
mounting a fourth electronic component on the second encapsulant to electrically connect with the second interconnection structure.

9. The method of claim 7, wherein the first interconnection structure and/or the second interconnection structure comprise a copper pin.

10. The method of claim 1, wherein the second electronic component has a height greater than that of the first electronic component.

11. The method of claim 1, wherein the first electronic component comprises a discrete device.

12. A semiconductor package, comprising:
a substrate having a top surface and a bottom surface, wherein the top surface of the substrate has a first region and a second region;
a first electronic component mounted on the first region;
a first interconnection structure mounted on the first region;
a first encapsulant encapsulating the first electronic component and the first interconnection structure, wherein the first encapsulant is formed in the first region but outside the second region;
a conductive pattern formed on the first encapsulant and electrically connected with the first interconnection structure;
a second electronic component mounted on the second region; and
a third electronic component mounted on the first encapsulant and electrically connected with the conductive pattern.

13. The semiconductor package of claim 12, further comprising:
a second encapsulant formed on the top surface of the substrate and encapsulating the first encapsulant, the second electronic component and the third electronic component.

14. The semiconductor package of claim 12, wherein a top surface of the first encapsulant is coplanar with a top surface of the first interconnection structure.

15. The semiconductor package of claim 14, wherein the third electronic component is mounted on the first encapsulant by flip-chip bonding.

16. The semiconductor package of claim 12, further comprising:
a second interconnection structure mounted on the first encapsulant and electrically connected with the conductive pattern; and
a second encapsulant formed on the top surface of the substrate and encapsulating the first encapsulant, the second electronic component, the third electronic component and the second interconnection structure.

17. The semiconductor package of claim 16, further comprising:
a fourth electronic component mounted on the second encapsulant and electrically connected with the second interconnection structure.

18. The semiconductor package of claim 16, wherein the first interconnection structure and/or the second interconnection structure comprise a copper pin.

19. The semiconductor package of claim 12, wherein the second electronic component has a height greater than that of the first electronic component.

20. The semiconductor package of claim 12, wherein the first electronic component comprises a discrete device.
